(19) United States
(12) Patent Application Publication
(10) Pub. No.: US 2020/0243468 A1
(43) Pub. Date: Jul. 30, 2020

(54) ELECTRONIC DEVICE

(71) Applicant: FUJITSU COMPONENT LIMITED, Tokyo (JP)

(72) Inventors: Shunichi Kamata, Tokyo (JP); Tatsuhiro Mori, Tokyo (JP); Takashi Sugata, Tokyo (JP); Takeshi Okuyama, Tokyo (JP)

(21) Appl. No.: 16/750,180

(22) Filed: Jan. 23, 2020

(30) Foreign Application Priority Data
Jan. 29, 2019 (JP) 2019-012838

(51) Int. Cl. H01L 23/00; G02B 6/42; G02B 6/43

(52) U.S. Cl. CPC H01L 24/13; G02B 6/43; G02B 6/4212; G02B 6/4281

(57) ABSTRACT

An electronic device includes a circuit board, an electronic element, multiple connection bumps, a preventive bump, and a sidefill. The electronic element is mounted on the circuit board. The connection bumps are connected to the electronic element. The preventive bump is provided between the connection bumps. The sidefill surrounds the electronic element.

### CROSS-REFERENCE TO RELATED APPLICATION

The present application is based on and claims priority to Japanese patent application No. 2019-012838, filed on Jan. 29, 2019, the entire contents of which are incorporated herein by reference.

### BACKGROUND OF THE INVENTION

### 1. Field of the Invention

The present invention relates to electronic devices.

### 2. Description of the Related Art

According to optical modules in which a light emitter or a light receiver is mounted on a substrate, holes are provided in the substrate to allow light emitted from the light emitter or received by the light receiver to pass through the substrate. (See Japanese Laid-open Patent Publication Nos. 2017-125956, 2014-102399, 9-64238, and 2016-181627.)

### SUMMARY OF THE INVENTION

According to an aspect of the present invention, an electronic device includes a circuit board, an electronic element, multiple connection bumps, a preventive bump, and a sidefill. The electronic element is mounted on the circuit board. The connection bumps are connected to the electronic element. The preventive bump is provided between the connection bumps. The sidefill surrounds the electronic element.

### BRIEF DESCRIPTION OF THE DRAWINGS

FIGS. 1A through 1D are diagrams illustrating a process of manufacturing an optical module;

FIGS. 2 through 4 are diagrams illustrating the optical module;

FIGS. 5 and 6 are diagrams illustrating a sidefill of the optical module;

FIG. 7 is a diagram illustrating an optical module according to a first embodiment;

FIGS. 8 and 9 are sectional views of the optical module;

FIGS. 10 and 11 are diagrams illustrating a sidefill of the optical module;

FIG. 12 is a flowchart of manufacture of an optical module;

FIGS. 13A through 13H are diagrams illustrating a process of manufacturing an optical module;

FIG. 14 is a flowchart of a process of manufacturing an optical module according to a second embodiment;

FIGS. 15A through 15E are diagrams illustrating the process of manufacturing an optical module according to the second embodiment;

FIG. 16 is a flowchart of a process of manufacturing an optical module according to a third embodiment;

FIGS. 17A through 17H are diagrams illustrating the process of manufacturing an optical module according to the third embodiment;

FIG. 18 is a flowchart of a process of manufacturing an optical module according to a fourth embodiment; and

FIGS. 19A through 19H are diagrams illustrating the process of manufacturing an optical module according to the fourth embodiment.

### DESCRIPTION OF THE EMBODIMENTS

According to the optical modules, sidefill of a thermosetting resin is formed around the light emitter or receiver for its reinforcement or protection. The resin, however, when applied and heated, may wet and spread to the inside of the light emitter or receiver to enter holes in the substrate. The resin is colored, and once the resin in the holes is cured, no light passes through the sidefill.

Embodiments of the present invention are described below. The same members or the like are referred to by the same reference numeral, and duplicate description thereof is omitted.

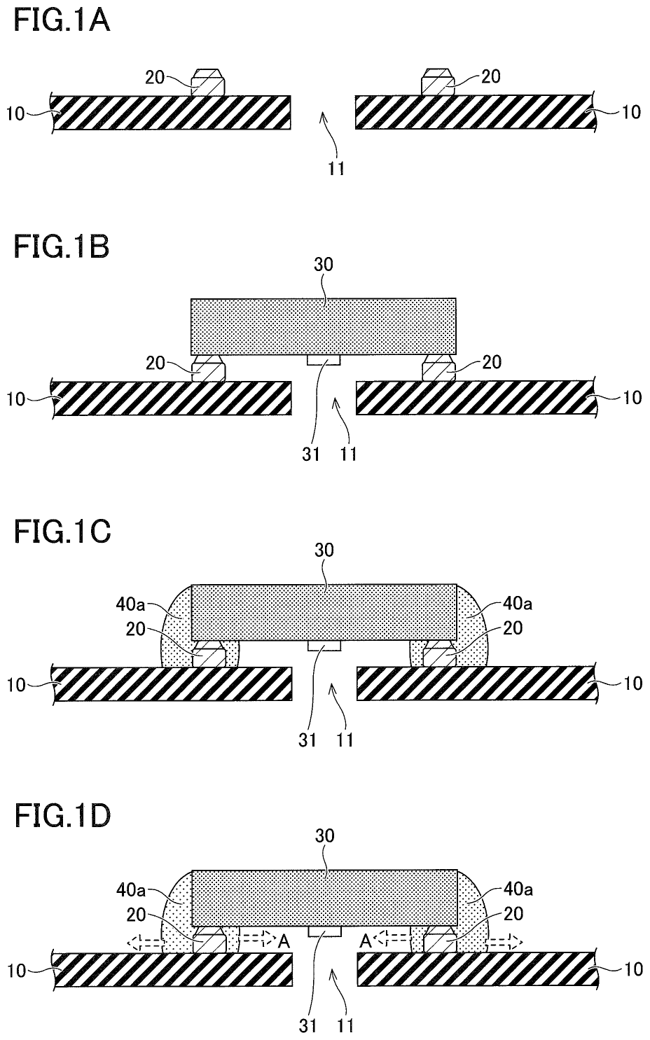

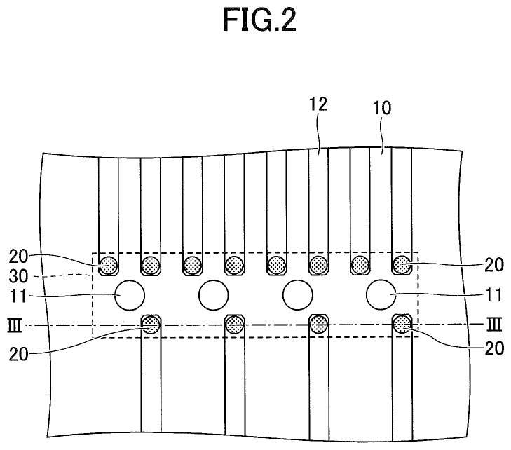

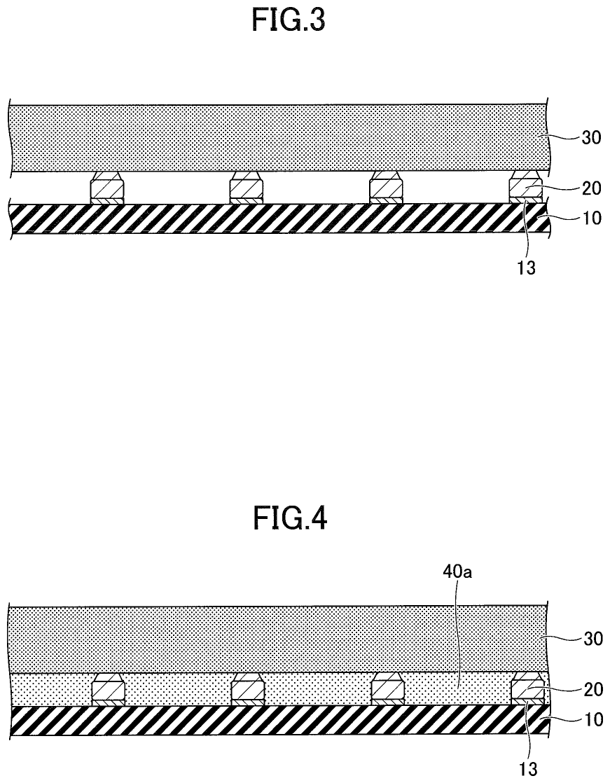

According to an optical module, connection bumps 20 are formed on a circuit board 10 as illustrated in FIG. 1A. FIG. 2 is a plan view of the circuit board 10. FIG. 3 is a sectional view of the circuit board 10 of FIG. 2, taken along the line III-III. As illustrated in FIGS. 2 and 3, the bumps 20 are formed of, for example, gold on electrodes 13 (omitted in FIGS. 1A through 1D) connected to wiring patterns 12 formed on the board 10. In the board 10, holes 11 are formed at positions corresponding to the light emitting parts of a light emitter or the light receiving parts of a light receiver. Hereinafter, an element having a light-emitting or light-receiving function is referred to as “light emitter/receiver”, and light emitting parts and light receiving parts are collectively referred to as “light emitting/receiving parts.”

As illustrated in FIG. 1B, a light emitter/receiver 30 is mounted on the bumps 20. At this point, light emitting/receiving parts 31 and the holes 11 are aligned, and the terminals of the light emitter/receiver 30 and the bumps 20 are aligned.

Next, as illustrated in FIG. 1C, a thermosetting resin 40a for sidefill is applied around the light emitter/receiver 30. Next, the resin 40a is heated to be cured.

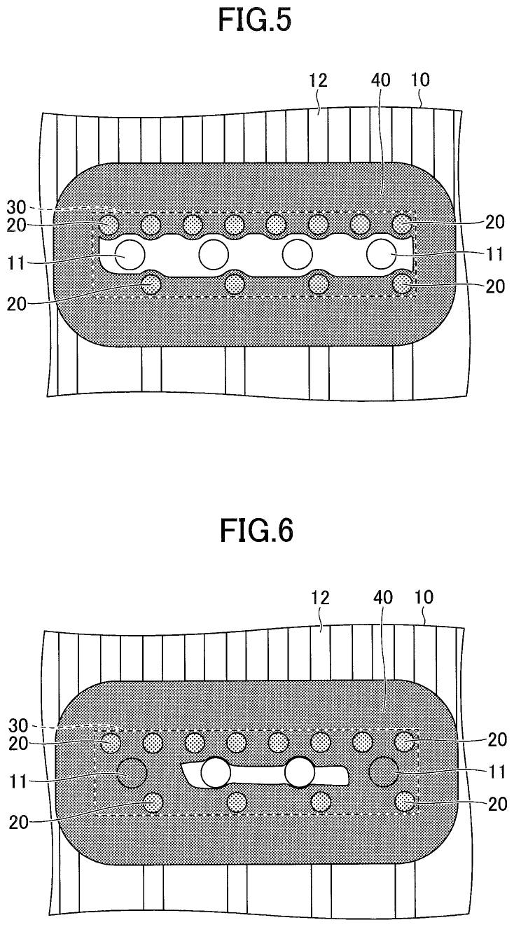

As illustrated in FIG. 4, the applied resin 40a enters and fills a gap between the light emitter/receiver 30 and the board 10. The wet and spread resin 40a is heated to be cured to form a sidefill 40.

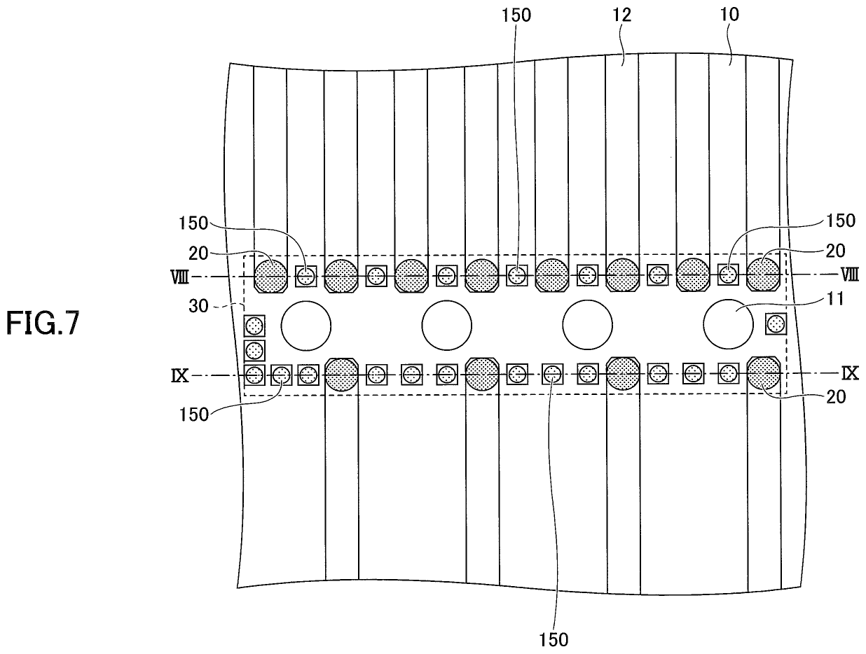

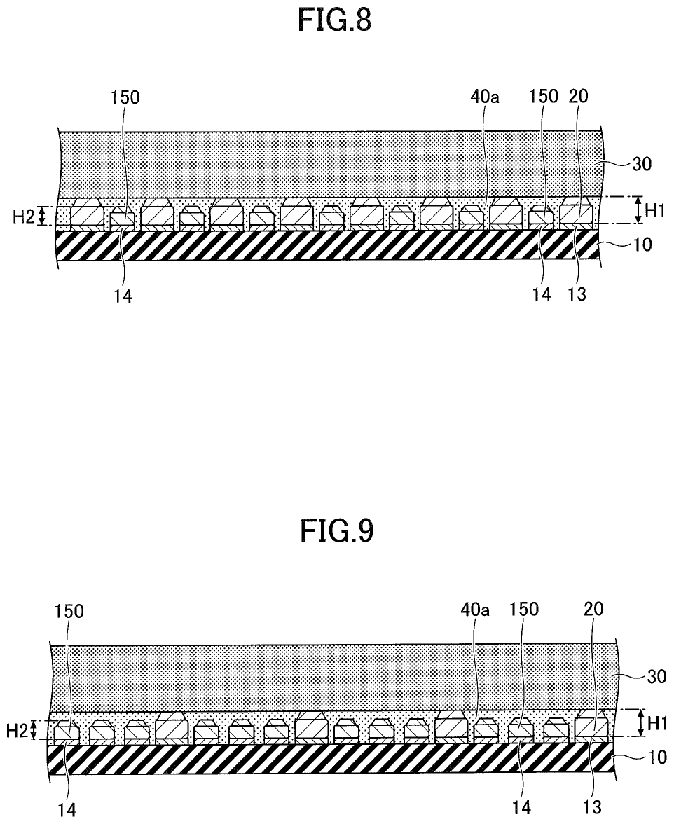

When heated, the resin 40a temporarily becomes less viscous and is then cured. When becoming less viscous, the resin 40a wets and spreads in the A direction of FIG. 1D on surfaces of the light emitter/receiver 30 and the board 10, and may reach and enter the holes 11. As illustrated in FIG. 5, when short of the holes 11, the sidefill 40 does not block light emitted or received by the light emitting/receiving parts 31. The sidefill 40, however, may reach the holes 11 to block light emitted or received by the light emitting/receiving parts 31 as illustrated in FIG. 6.

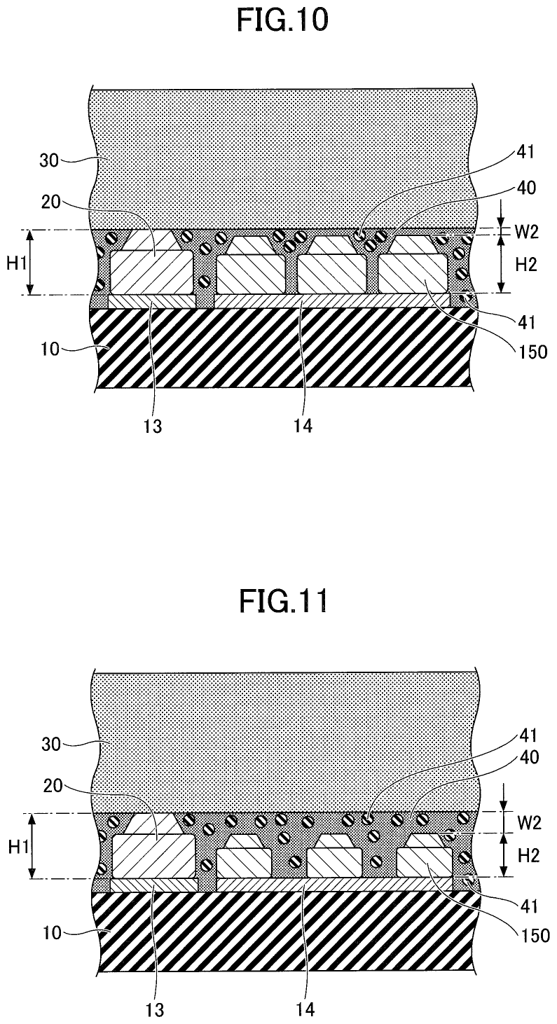

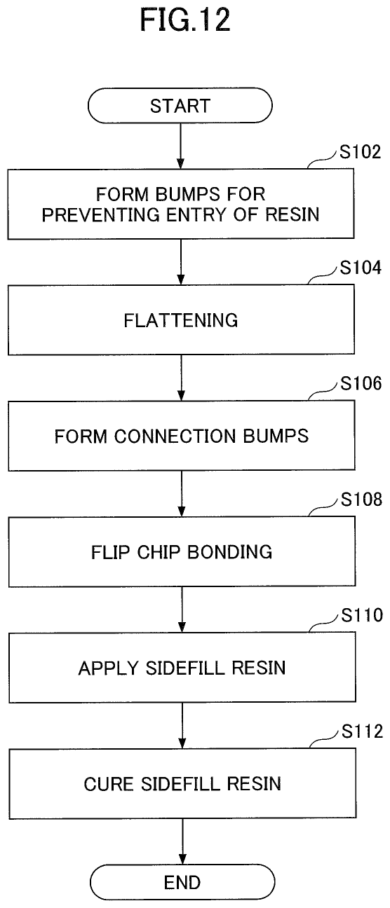

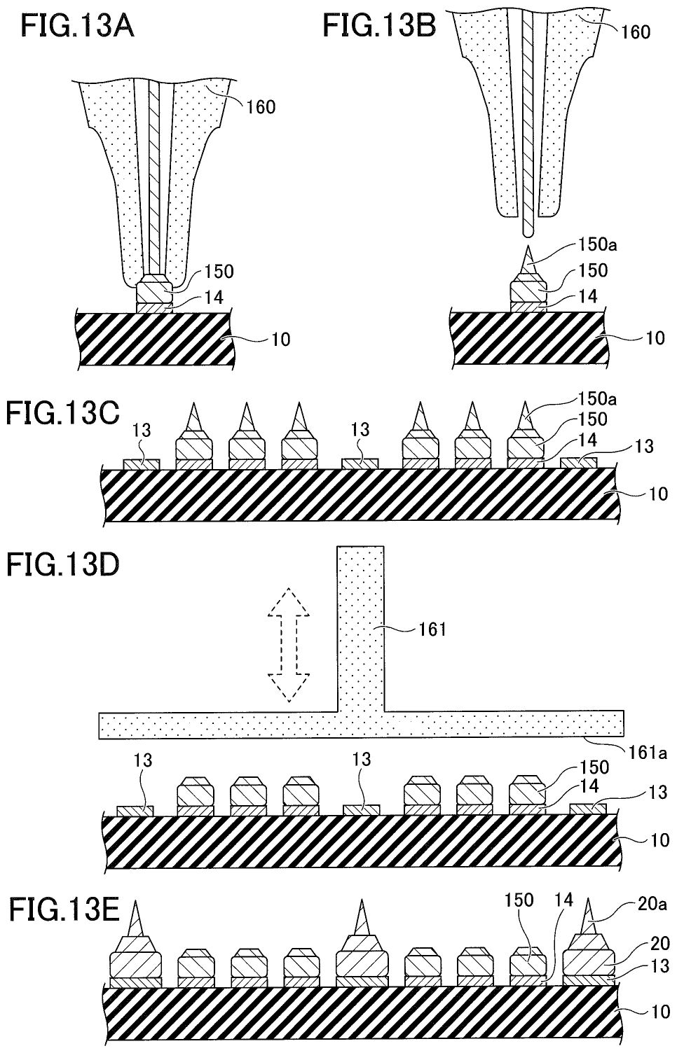

An optical module that is an example of an electronic device according to a first embodiment is described. FIG. 7 is a plan view of the optical module. FIG. 8 is a sectional view of the optical module of FIG. 7, taken along the one-dot chain line VIII-VIII. FIG. 9 is a sectional view of the optical module of FIG. 7, taken along the one-dot chain line IV-IV. According to the optical module, one or more preventive bumps 150 are provided between each adjacent two of the bumps 20. Referring to FIG. 7, the light emitter/receiver 30 is indicated by a dashed line, and the sidefill 40 is omitted. The bumps 20 have a circular shape of approximately 58 μm in diameter and have a height H1 of approximately 15 μm. The preventive bumps 150 are formed on electrodes 14, have a circular shape of 40 μm to 45 μm in diameter, and have a height H2 of 9 μm to 12 μm. The preventive bumps 150 are made of gold, silver, or copper.

The bumps 20 are electrically connected to terminals of the light emitter/receiver 30. The interval between the board 10 and the light emitter/receiver 30 is approximately 15 μm. The height H2 of the preventive bumps 150 is smaller than the height H1 of the bumps 20. Therefore, the preventive bumps 150 do not touch the light emitter/receiver 30.

After connecting the bumps 20 and the light emitter/receiver 30, the fluid resin 40a is applied around the light emitter/receiver 30 to enter a gap between the board 10 and the light emitter/receiver 30. According to this embodiment, the preventive bumps 150 are provided between the bumps 20. Therefore, the resin 40a is prevented from wetting and spreading inward beyond the area where the bumps 20 are provided and entering an area inside the bumps 20.

The preventive bumps 150 do not have to be electrically connected to the light emitter/receiver 30, but if the height H2 of the preventive bumps 150 is equal to the height H1, the preventive bumps 150 may contact the light emitter/receiver 30 to damage or apply stress to the light emitter/receiver 30. Therefore, according to this embodiment, the preventive bumps 150 are lower than the bumps 20. The number of the preventive bumps 150 provided between the bumps 20 is one in the area where the pitch of the bumps 20 is 100 μm in FIG. 8 and three in the area where the pitch of the bumps 20 is 200 μm in FIG. 9.

The resin 40a is formed of filler and resin. The filler is formed of silica having a minimum particle size of 3 μm to 4 μm, a maximum particle size of approximately 28 μm, and an average particle size of approximately 18 μm, for example. The filler content of the resin 40a is 60% to 70%. The resin 40a further includes epoxy resin, acid anhydride, and carbon black.

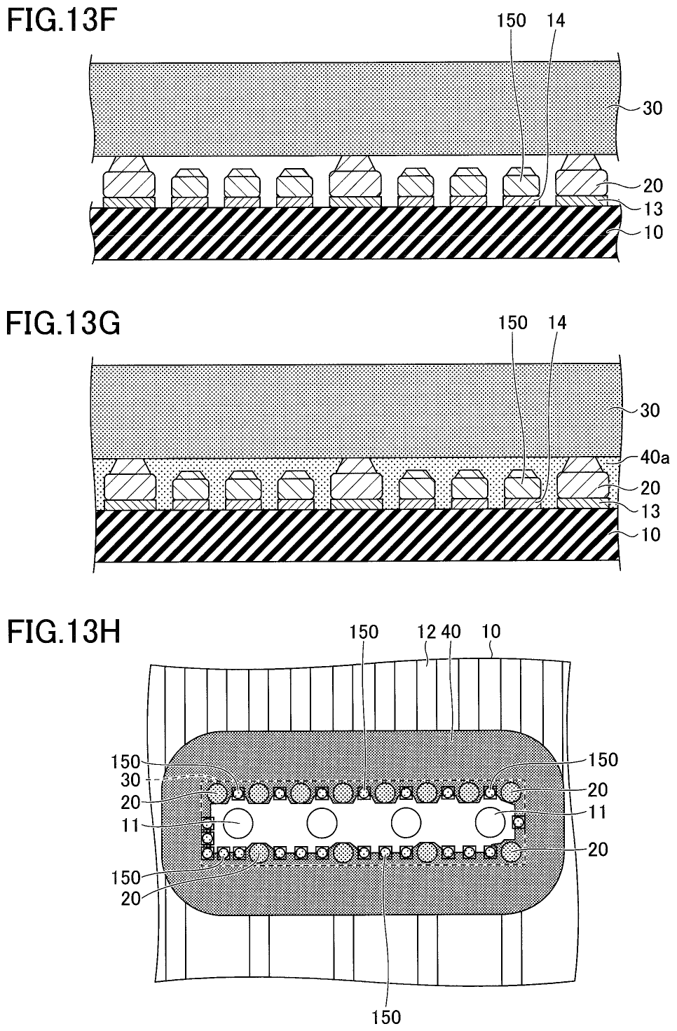

An interval W2 between the preventive bumps 150 and the light emitter/receiver 30 may be smaller than the minimum particle size of a filler 41 as illustrated in FIG. 10. For example, the height H2 of the preventive bumps 150 is 13 μm to 14 μm, and the interval W2 is 1 μm to 2 μm. When the interval W2 is smaller than the minimum particle size of the filler 41, the filler 41 does not enter a gap between the preventive bumps 150 and the light emitter/receiver 30. Because the gap between the preventive bumps 150 and the light emitter/receiver 30 is narrow, heat from the light emitter/receiver 30 is likely to be transferred to the preventive bumps 150 through the thin sidefill 40, and is further transferred to the board 10 through the electrodes 14. Therefore, heat dissipation is improved.

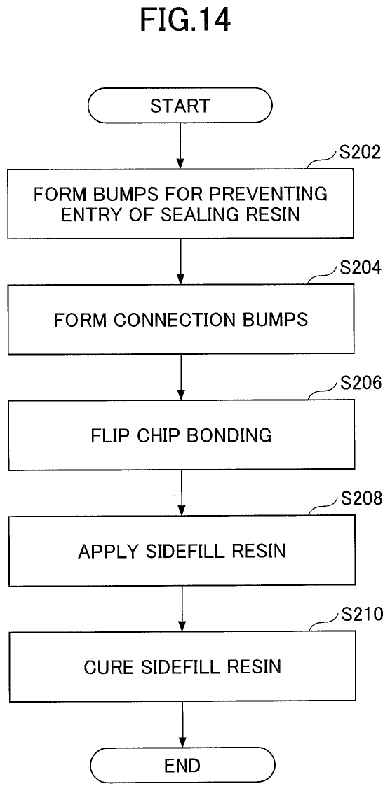

The interval W2 may be greater than the minimum particle size of the filler 41 as illustrated in FIG. 11. For example, the height H2 of the preventive bumps 150 is 9 μm to 10 μm, and the interval W2 is 5 μm to 6 μm. When the interval W2 is greater than the minimum particle size of the filler 41, the filler 41 enters the gap between the preventive bumps 150 and the light emitter/receiver 30. However, silica, which forms the filler 41, is relatively hard and has high strength. Therefore, the strength of the optical module is improved.

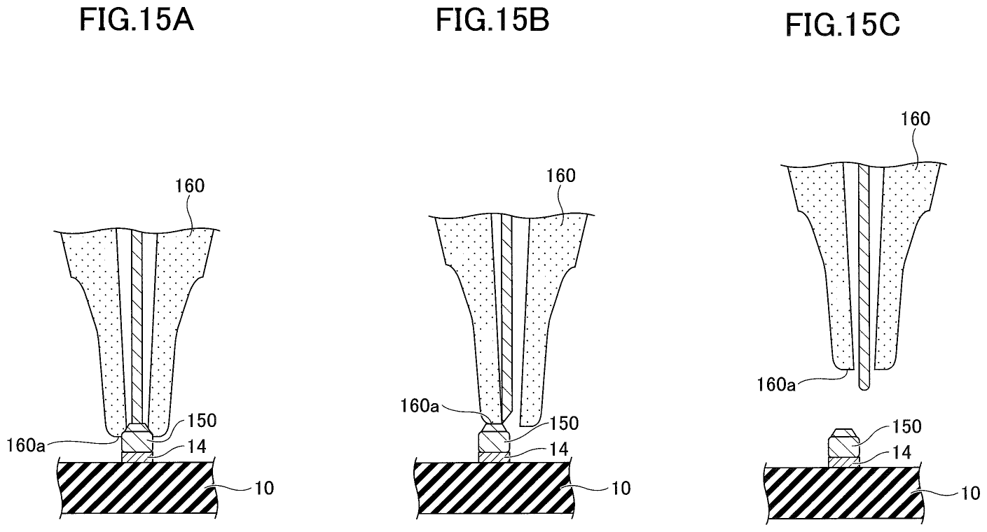

The manufacture of an optical module according to this embodiment is described with reference to FIG. 12.

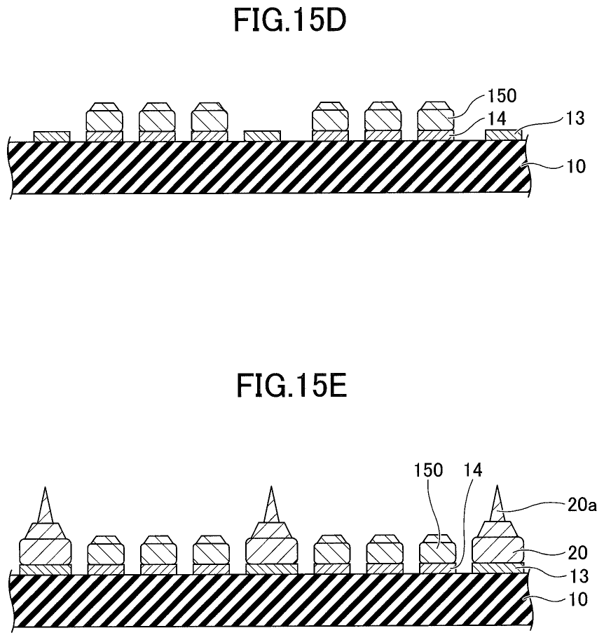

First, at step S102, stud bumps to become the preventive bumps 150 are formed using a wire bonder or a bump bonder. As illustrated in FIG. 13A, a capillary 160 of a wire bonder is brought closer to the electrode 14 to supply gold. Thereafter, as illustrated in FIG. 13B, the capillary 160 is moved away from the board 10. As a result, the preventive bump 150 having a pointed tip 150a is formed on the electrode 14. This process is repeatedly performed to form the preventive bumps 150 as illustrated in FIG. 13C. Next, at step S104, as illustrated in FIG. 13D, the tips 150a are pressed flat using, for example, a jig 161 having a flat surface 161a. The height of the preventive bumps 150 is, for example, approximately 10 μm.

Next, at step S106, as illustrated in FIG. 13E, stud bumps having pointed tips 20a to become the bumps 20 are formed on the electrodes 13. The stud bumps of FIG. 13E may be formed the same as in FIGS. 13A and 13B, but the stud bumps to become the bumps 20 are larger than the stud bumps to become the preventive bumps 150. Next, at step S108, as illustrated in FIG. 13F, the light emitter/receiver 30 is placed on the bumps 20 and is mounted on the board 10 by flip chip bonding. At this point, the tips 20a are pressed, and the height of the bumps 20 is, for example, approximately 15 μm.

Next, at step S110, the resin 40a is applied around the light emitter/receiver 30. As illustrated in FIG. 13G, the resin 40a wets and spreads into a gap between the board 10 and the light emitter/receiver 30. Thereafter, at step S112, the resin 40a is cured to form the sidefill 40. The resin 40a is blocked by the preventive bumps 150 and is cured without wetting and spreading inward beyond the preventive bumps 150 as illustrated in FIG. 13H.

While an optical module is described as an example of an electronic device according to this embodiment, the present invention may also be applied to an electronic device including a movable part such as a micro-electro-mechanical system (MEMS) or a surface acoustic wave (SAW) filter instead of a light emitter/receiver.

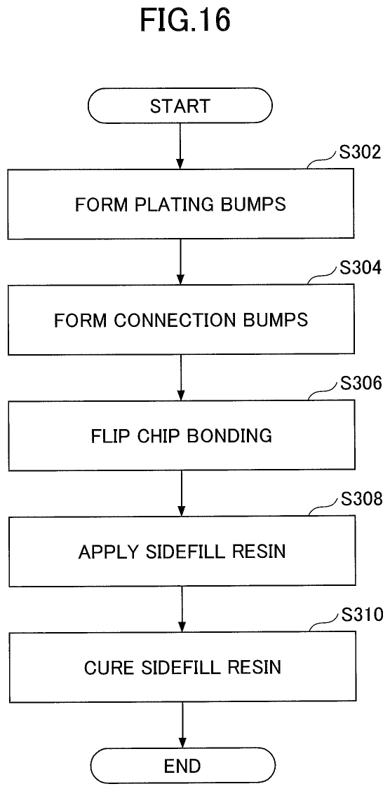

Manufacture of an optical module according to a second embodiment is described with reference to FIG. 14.

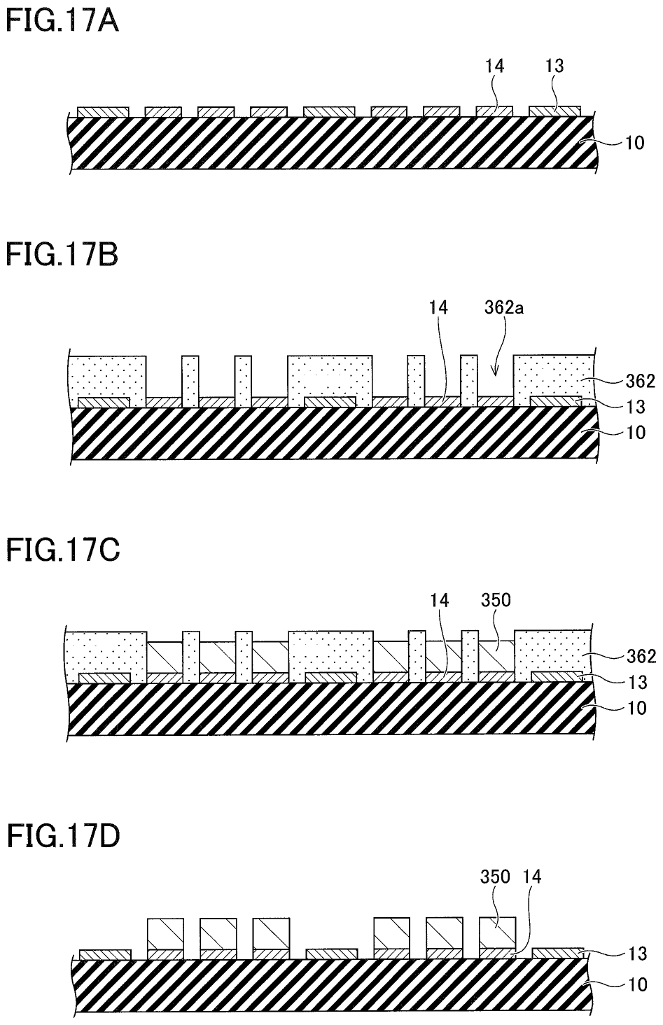

First, at step S202, the preventive bumps 150 are formed on the electrodes 14 using a wire bonder or a bump bonder. As illustrated in FIG. 15A, the capillary 160 is brought closer to the electrode 14 to supply gold. Thereafter, the capillary 160 is moved in a direction parallel to the surface of the board 10 to shape the top of the stud bump with a surface 160a of the capillary 160 as illustrated in FIG. 15B, and the capillary 160 is moved away from the board 10 as illustrated in FIG. 15C. As a result, the preventive bump 150 with a flat top is formed. This process is repeatedly performed to form the preventive bumps 150 as illustrated in FIG. 15D. The height of the preventive bumps 150 is, for example, approximately 10 μm.

Next, at step S204, as illustrated in FIG. 15E, stud bumps having the pointed tips 20a to become the bumps 20 are formed on the electrodes 13. The stud bumps of FIG. 15E may be formed the same as the stud bumps to become the preventive bumps 150. Next, at step S206, as illustrated in FIG. 13F, the light emitter/receiver 30 is mounted on the board 10 by flip chip bonding. At this point, the tips 20a are pressed.

Next, at step S208, the resin 40a is applied around the light emitter/receiver 30. The resin 40a wets and spreads into a gap between the board 10 and the light emitter/receiver 30. Thereafter, at step S210, the resin 40a is cured to form the sidefill 40. The resin 40a is blocked by the preventive bumps 150 and is cured without wetting and spreading inward beyond the preventive bumps 150.

The order of steps S202 and S204 may be reversed.

In other respects than those described above, the second embodiment may be the same as the first embodiment.

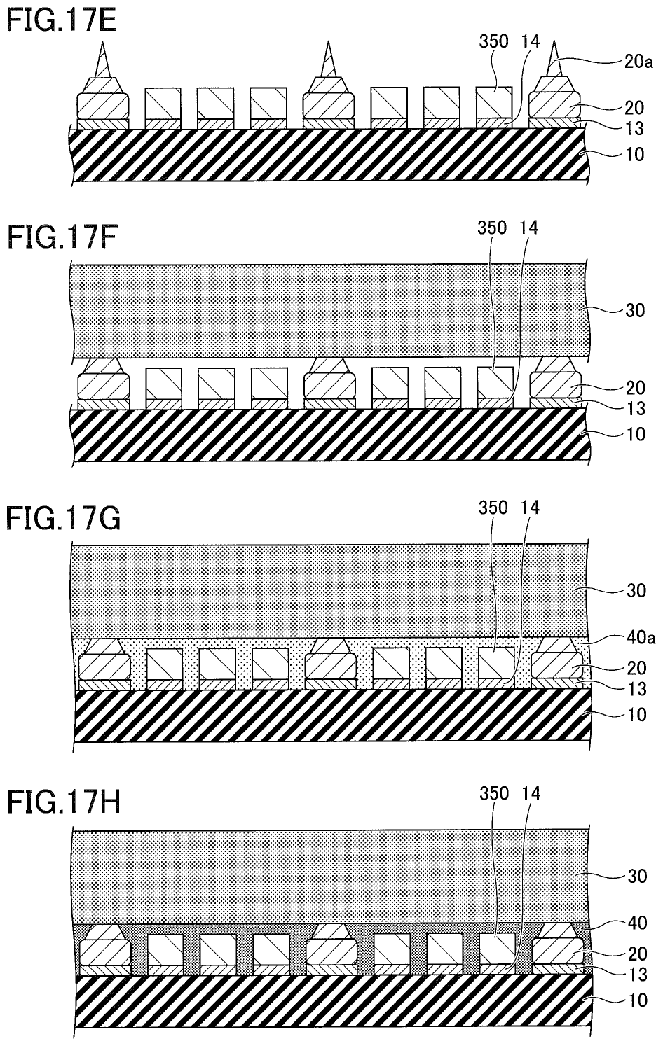

A third embodiment, according to which preventive bumps are formed by plating, is described with reference to FIG. 16.

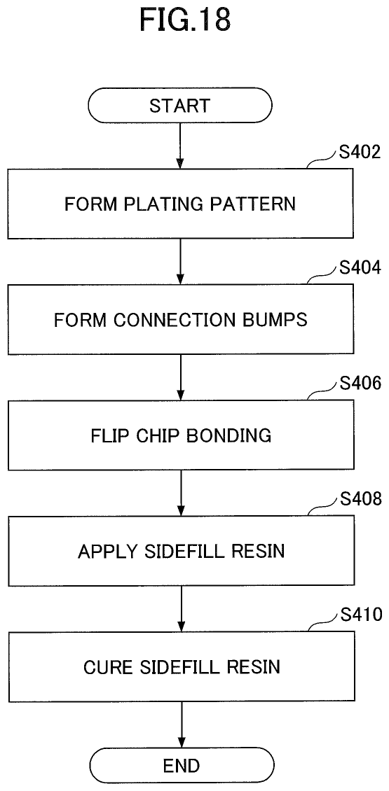

First, at step S302, preventive bumps 350 are formed by plating. As illustrated in FIGS. 17A and 17B, photoresist is applied on the board 10, and is exposed to light and developed with an exposure apparatus to form a resist pattern 362. The resist pattern 362 includes openings 362a that expose the electrodes 14 in an area where the preventive bumps 350 are to be formed. Next, as illustrated in FIG. 17C, metal such as copper is deposited on the electrodes 14 by electroplating to form the preventive bumps 350. Thereafter, as illustrated in FIG. 17D, the resist pattern 362 is removed. The height of the preventive bumps 350 formed by plating is, for example, approximately 10 μm.

Next, at step S304, as illustrated in FIG. 17E, stud bumps to become the bumps 20 are formed on the electrodes 13. The stud bumps may be formed in the same manner as illustrated in FIGS. 13A and 13B. Next, at step S306, as illustrated in FIG. 17F, the light emitter/receiver 30 is mounted on the board 10. At this point, the tips 20a are pressed.

Next, at step S308, the resin 40a is applied. As illustrated in FIG. 17G, the resin 40a wets and spreads into a gap between the board 10 and the light emitter/receiver 30. Next, at step S310, the resin 40a is cured to form the sidefill 40 as illustrated in FIG. 17H. The resin 40a is blocked by the preventive bumps 350 and is cured without wetting and spreading inward beyond the preventive bumps 350.

The bumps 20 as well may be formed by plating. In other respects than those described above, the third embodiment may be the same as the first embodiment.

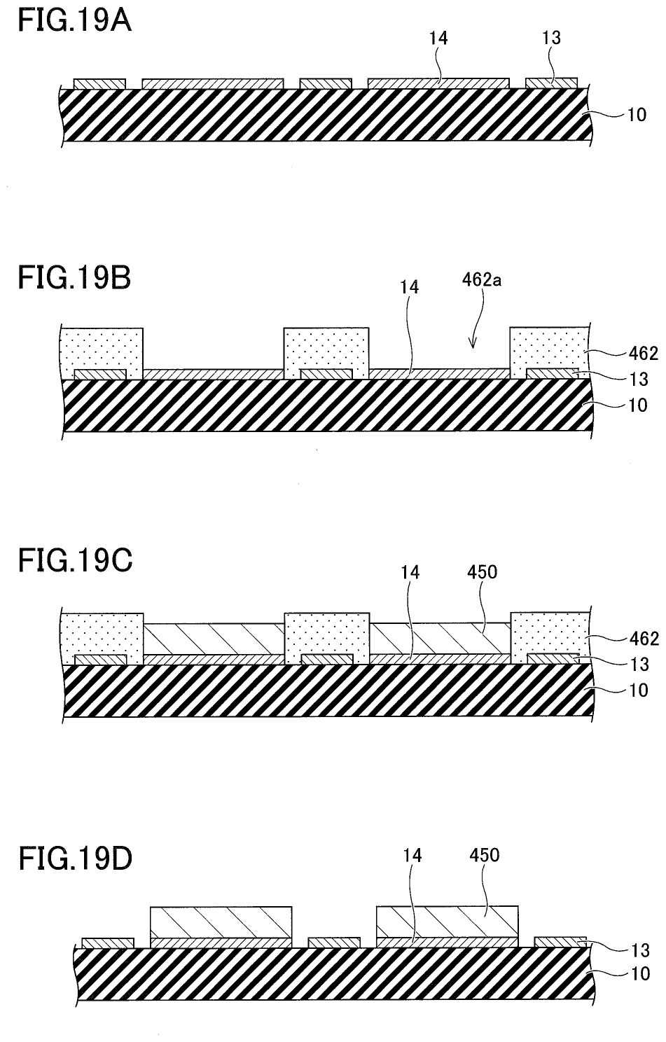

According to a fourth embodiment, a pattern that prevents entry of resin is formed by plating. Manufacture of an optical module according to this embodiment is described with reference to FIG. 18. The preventive pattern is an embodiment of preventive bumps.

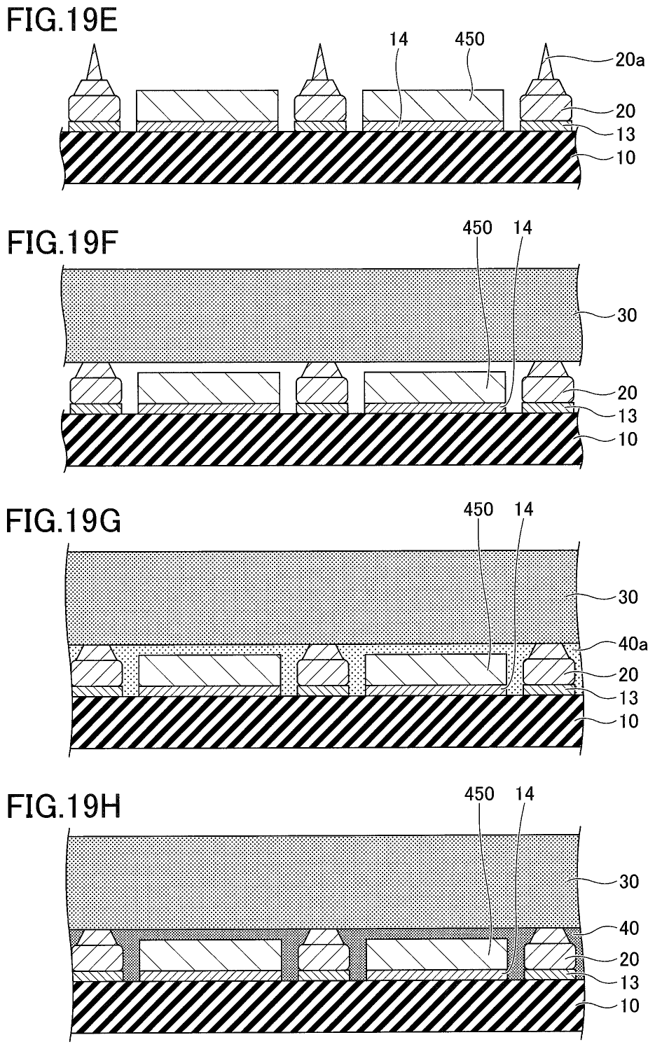

First, at step S402, a preventive pattern 450 is formed by plating. As illustrated in FIGS. 19A and 19B, photoresist is applied on the board 10 to form a resist pattern 462. The resist pattern 462 includes openings 462a that expose the electrodes 14 in an area where the preventive pattern 450 is to be formed. Thereafter, as illustrated in FIG. 19C, metal such as copper is deposited on the electrodes 14 by electroplating to form the preventive pattern 450, and, as illustrated in FIG. 19D, the resist pattern 462 is removed using an organic solvent. The height of the preventive pattern 450 is, for example, approximately 10 μm.

Next, at step S404, as illustrated in FIG. 19E, stud bumps to become the bumps 20 are formed. Next, at step S406, as illustrated in FIG. 19F, the light emitter/receiver 30 is mounted on the board 10.

Next, at step S408, the resin 40a is applied around the light emitter/receiver 30. As illustrated in FIG. 19G, the resin 40a wets and spreads into a gap between the board 10 and the light emitter/receiver 30. Thereafter, at step S410, the resin 40a is cured to form the sidefill 40 as illustrated in FIG. 19H. The resin 40a is cured without wetting and spreading inward beyond the preventive pattern 450.

In other respects than those described above, the fourth embodiment may be the same as the third embodiment.

Although one or more embodiments of the present invention have been described heretofore, the present invention is not limited to these embodiments, and variations and modifications may be made without departing from the scope of the present invention.

What is claimed is:

1. An electronic device comprising:
a circuit board;
an electronic element mounted on the circuit board;
a plurality of connection bumps connected to the electronic element;
a preventive bump provided between the connection bumps; and
a sidefill surrounding the electronic element.

2. The electronic device as claimed in claim 1, wherein a height of the preventive bump is smaller than a height of the connection bumps.
